(19) United States
(12) Patent Application Publication
(10) Pub. No.: US 2025/0103766 A1
(43) Pub. Date: Mar. 27, 2025

(54) METHOD OF ACHIEVING HARD REAL-TIME BY NON-REAL-TIME SYSTEM IN HARDWARE-IN-LOOP SIMULATION, STORAGE MEDIUM, PROCESSOR AND ELECTRONIC DEVICE

(71) Applicant: SHANGHAI TOSUN TECHNOLOGY LTD., Shanghai (CN)

(72) Inventors: Chu LIU, Shanghai (CN); Yueyin XIE, Shanghai (CN); Mang MO, Shanghai (CN)

(73) Assignee: SHANGHAI TOSUN TECHNOLOGY LTD., Shanghai (CN)

(21) Appl. No.: 18/371,527

(22) Filed: Sep. 22, 2023

(51) Int. Cl. G06F 30/20

(52) U.S. Cl. CPC G06F 30/20

(57) ABSTRACT

A method and system for achieving hard real-time by a non-real-time system in a hardware-in-loop simulation is provided. The method of achieving hard real-time by the non-real-time system in the hardware-in-loop simulation includes: creating a real-time model task and forming a task program; automatically reading, by the task program, computer configuration and determining a number Z of kernels of a processor of a current computer device; when the number Z of the kernels is not greater than X, setting a thread number to n=1 to execute the real-time model task, and otherwise, setting the thread number to n=(Z−X)/Y to execute the real-time model task, wherein Y represents a thread number of one physical core of the processor.

### TECHNIC FIELD

The present disclosure relates to the field of vehicular software development technologies, and in particular to a method of achieving hard real-time by a non-real-time system in a hardware-in-loop simulation.

### BACKGROUND

In order to execute a hardware-in-loop simulation task, it is usually required to rely on a real-time system and deploy the execution of the task in the real-time system. The real-time system is in another computer rather than in the local and hence has to perform any action by remote calling, leading to the problem of inability to directly observe those related signals and key signals determining algorithm function and performance.

### SUMMARY

The present disclosure provides a method of achieving hard real-time by a non-real-time system in a hardware-in-loop simulation, including:
creating a real-time model task and forming a task program;
automatically reading, by the task program, computer configuration and determining a number Z of processor kernels of a current computer device; when the number Z of the kernels is not greater than X, setting a thread number to n=1 to execute the real-time model task, and otherwise, setting the thread number to n=(Z−X)/Y to execute the real-time model task,
where Y represents a thread number of one physical core of the processor.

The summary of the present disclosure aims to provide brief descriptions for the subjects of the specification. Thus, it should be understood that the above features are only illustrative and shall not be interpreted as narrowing the scope or essence of the subject of the specification in any way.

Other features, aspects and advantages of the subjects of the present disclosure will become apparent by way of the specific embodiments, drawings and claims.

### BRIEF DESCRIPTION OF THE DRAWINGS

In order to more clearly describe the technical solutions in the specific embodiments of the present disclosure or the prior arts, the drawings required for descriptions of the specific embodiments or the prior arts will be briefly introduced. Apparently, the drawings described hereunder are only some embodiments of the present disclosure. Those skilled in the art can also obtain other drawings based on these drawings without making creative work.

FIG. 1 is a schematic diagram illustrating steps of a method of achieving hard real-time by a non-real-time system in a hardware-in-loop simulation according to some embodiments of the present disclosure.

FIG. 2 is a principle block diagram illustrating a system for achieving hard real-time by a non-real-time system in a hardware-in-loop simulation according to some embodiments of the present disclosure.

FIG. 3 is a principle block diagram illustrating an electronic device according to some embodiments of the present disclosure.

### DETAILED DESCRIPTION OF THE EMBODIMENTS

In order to make the object, technical solutions and advantages of the embodiments of the present disclosure clearer, the technical solutions of the present disclosure will be fully and clearly described in combination with drawings. Apparently, the embodiments described herein are only some embodiments rather than all embodiments. All other embodiments obtained by those skilled in the art based on these drawings without making creative work shall fall within the scope of protection of the present disclosure.

At present, when similar softwares perform a hardware-in-loop task, hard real time is usually achieved by a real-time system. This requires more hardware investment and deployment costs. But, in a method of achieving hard real time by a non-real-time system in a hardware-in-loop simulation in some embodiments, hard real time can be achieved by the non-real-time system without adding the real-time system.

Specifically, one or more embodiments provide a method of achieving hard real time by a non-real-time system in a hardware-in-loop simulation, which includes:

Step S101, creating a real-time model task and forming a task program;

Step S102, automatically reading, by the task program, computer configuration and determining a number Z of processor kernels of a current computer device; when the number Z of the kernels is not greater than X, setting a thread number to n=1 to execute the real-time model task, and otherwise, setting the thread number to n=(Z−X)/Y to execute the real-time model task, wherein Y represents a thread number of one physical core of the processor.

In the method of achieving hard real time by the non-real-time system in the hardware-in-loop simulation in some embodiments, when the hardware-in-loop simulation task is executed, a virtual hard real time environment can be directly run in a personal computer to achieve hard real time, namely, it can be done without purchasing the real-time system. Further, because all operations are performed locally, the development test efficiency is greatly increased and the flexibility of simulation signal observation and modification is improved. For example, when it is desired to observe a local variable, local program codes can be modified at any time to add print information, observation information, curve plotting signal information and other function information. Once locally compiled, the program codes can be immediately run with high efficiency. But, in a conventional method, it is required to, for the local variable, design an input and output interface, update a simulation model interface table and compile the entire code program and re-deploy the real-time system software and then remotely run the simulation model and then perform observation.

In combination with the accompanying drawings, various non-limiting implementations of the embodiments of the present disclosure will be described in details below.

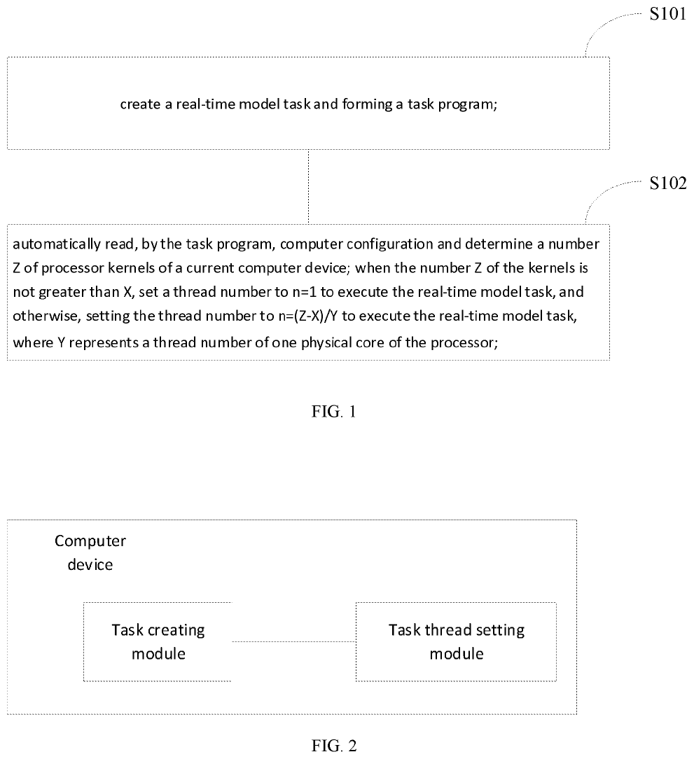

As shown in FIG. 1, one or more embodiments provide a method of achieving hard real time by a non-real-time system in a hardware-in-loop simulation, including:
creating a real-time model task and forming a task program;
automatically reading, by the task program, computer configuration and determining a number Z of processor kernels of a current computer device; when the number Z of the kernels is not greater than X, setting a thread number to n=1 to execute the real-time model task, and otherwise, setting the thread number to n=(Z−X)/Y to execute the real-time model task,
wherein Y represents a thread number of one physical core of the processor.

Specifically, the real-time model task is a timing program. The real-time model task is created by creating a timer first. After the timer is created, a period of the timer is set, for example, to 500 microseconds. Next, based on the period, timed call is performed on the step function of the model, and the formed task program is a code module for simulation of the real-time model task.

The number Z of the processor kernels is determined by the processor model and different processor models may have distinctly different numbers Z of kernels. For example, the kernel number Z of Intel Xeon Platinum 9282 is 56 whereas the kernel number Z of the Intel Core i5-2520M is 2.

When Z is not greater than X, it indicates that the current computer has a weak performance and is unable to allocate multiple threads to execute simulation and otherwise the computer will be frozen. At this time, it is proper for a single thread to execute the real-time model task, namely, the thread number is set to n=1 to execute the real-time model task.

When Z is greater than X, in order to prevent the computer to allocate multiple threads to execute simulation in a case of weak performance, it is required to limit a minimum value of X, namely, limit the minimum value of the kernel number Z of the computer executing the simulation task with multiple threads. In an extreme case, when X=0, the thread number n=Z/Y is just equal to the number of the true physical cores; when X is not 0, it indicates that X/Y true physical cores are reserved as own cores not involved in simulation, so as to ensure smooth operation of the software system and other softwares.

As one implementation in some embodiments, setting the thread number to n=1 to execute the real-time model task includes:
defining a real-time time interval m for execution of the real-time model task;
obtaining a current time t by the thread in real time, and determining, in real time, whether the current time t is greater than a next execution time t_next,
when t>t_next, determining t_next=t_next+m and executing the real-time model task at the same time.

It should be noted that when the real-time model task is executed for the first time, t_next=m, and t=0.

Specifically, in combination with an example, detailed descriptions are made on the method of executing the real-time model task when n=1.

If X=4, when the processor model of the computer device is Intel Core i5-2520M, the kernel number Z is 2 less than 4, which indicates that the current computer device has weak performance and is unable to allocate multiple threads to execute simulation, and otherwise, the computer will be frozen. At this time, it is proper for a single thread to execute the real-time model task, namely, the thread number is set to n=1 to execute the real-time model task.

Since there is only one thread to execute the real-time model task, there is no preemption for multiple threads when the operation of determining whether the current time t is greater than a next execution time t_next is performed. Therefore, it is no need to perform thread synchronization by use of critical section or the like, so as to reduce performance overhead incurred by the introduction of the critical section. But, the defect of the single thread is also reflected. When the processor time slice of the thread is suspended due to operating system scheduling, the locking accuracy of the time of t_next will be lowered.

When the single thread executes the real-time model task, the real-time time interval for execution of the real-time model task is set to m=500 microseconds. The pseudocodes for the thread to execute the real-time model task are as follows:

```
m = 0.00005;
while (is_running) {
    t = get_current_time_stamp_us( );
    if (t >t_next){
      t_next_ = t_next + m;
      run_model_task( );
    }
  other_task( );
  }
```

Wherein “is_running” is a simulation running enable flag; when the simulation is terminated by a user, or exited naturally, the flag is false and the algorithm will no longer executes while cycle; “get_current_time_stamp_us( )” is an internal function of simulation system, used to obtain a timestamp of the current time measured in the unit of microsecond; “run_model_task( )” is an internal function of simulation system, used to periodically call the step function of the model; “other_task( )” is other tasks of simulation system, for example, Sleep(1) can be executed therein to reduce the consumption of the current processor for the processor time.

As one implementation in some embodiments, when the thread number is n=(Z−X)/Y, and the kernel number Z is greater than X, it indicates that it is proper for the processor of the current computer device to enable multi-thread simulation. The method of executing the real-time model task includes:
defining a real-time time interval m for execution of the real-time model task;
obtaining, by each thread, the corresponding current time t in real time at the same time, and determining whether the corresponding current time t is greater than a next execution time t_next;
when at least one thread detects t>t_next, the thread attempts to enter a critical section, and at this time, other threads are blocked from entering the critical section; after the thread successfully enters the critical section, the previous flag for the thread to determine t>t_next is invalid, and thus, the thread successfully entering the critical section performs the following contents in the critical section:
repetitively obtaining the current time t and determining whether the current time t is greater than a next execution time t_next;
if yes, determining t_next=t_next+m and executing the real-time model task at the same time, and exiting the critical section;
if not, directly exiting the critical section.

Specifically, in combination with an example, the method of executing the real-time model task when n=(Z−X)/Y is detailed below:

It is supposed that X=2, and Y=2. When the processor model of the computer device is Intel Core i7-8700, the kernel number Z is 6 greater than 2, and hence, the thread number is set to n=(Z−X)/Y=(6−2)/2=2 to execute the real-time model task.

Two threads are defined as thread 0 and thread 1.

When the real-time time interval for execution of the real-time model task is set to m=500 microseconds, the pseudocodes for each thread to execute the model task are as follows:

```
m = 0.00005;
while (is_running) {
  t = get_current_time_stamp_us( );
  if (t >t_next){
    EnterCriticalSection(FSection);
    t = get_current_time_stamp_us( );
    if (t >t_next){
      t_next_ = t_next + m;
      run_model_task( );
    }
    LeaveCriticalSection(FSection);
    }
    other_task( );
  }
```

wherein “is_running” is a simulation running enable flat; when the simulation is terminated by a user, or exited naturally, the flag is false and the algorithm will no longer executes while cycle; “get_current_time_stamp_us( )” is an internal function of simulation system, used to obtain a timestamp of the current time measured in the unit of microsecond; “EnterCriticalSection” is an API function of Windows system for entering the critical section; “FSection” is a critical section object shared by multiple threads; “LeaveCriticalSection” an API function of Windows system for exiting the critical section; “run_model_task( )” is an internal function of simulation system, used to periodically call the step function of the model; “other task( )” is other tasks of simulation system, for example, Sleep(1) can be executed therein to reduce the consumption of the current processor for the processor time.

The above pseudocodes effectively relieve the case of the reduced simulation time accuracy resulting from suspension of the processor time of the single thread due to system scheduling, and in other words, the simulation time accuracy can be effectively guaranteed by the above method, so as to ensure the simulation real-timeness.

The threads unsuccessfully entering the critical section are blocked from entering the critical section until the thread entering the critical section leaves the critical section and then start a next attempt.

Taking the method of executing the real-time model task when the thread number is set to n=2 as an example, when the thread 0 fails to determine a next execution time t_next due to system scheduling, and it is highly possible that the thread 1 determines the next execution time t_next and when detecting t>t_next, successfully enters the critical section, so as to preemptively execute the model task. At this time, the thread 0 is blocked in the code lines for entering the critical section. Only when the thread 1 completes the execution of the real-time model task and exits the critical section can the thread 0 start determining whether the current time t is greater than a next execution time t_next. If the thread 0 successfully enters the critical section at this time, it can update the current time t once, namely, repetitively obtain the current time t and determine the current time t is already less than the next execution time t_next (the next execution time t_next is already updated by the thread 1), and thus, the thread 0 will not execute the real-time model task but exit the critical section immediately to wait for a next determination.

The thread successfully entering the critical section is determined by the critical section independently, and in other words, the thread successfully entering the critical section is determined randomly by Windows system.
t_next is a common global variable of the threads, and that is, multiple threads can access a same variable at the same time. Various threads can share and access a same variable, and thus any thread can immediately attempt to enter the critical section once firstly finding the current time t is greater than the next execution time t_next, which effectively relieves the case of the reduced simulation time accuracy resulting from cancellation of the processor time of the single thread due to system scheduling, effectively ensuring the simulation time accuracy.

Each set thread occupies one processor physical core, including:
an index of the processor physical core occupied by each thread being equal to a value obtained by performing Modulo Operation on the corresponding thread index and a total number of processor physical cores.

Each set thread occupies one processor physical core to bring the computer device to optimal performance.

For example, there are a total of 10 threads, and a total of 8 processor physical cores and thus, the index of the processor physical core occupied by the thread 0 is a value obtained by performing Modulo Operation on 0 and 8, where the value is 0; and the index of the processor physical core occupied by the thread 9 is a value obtained by performing Modulo Operation on 9 and 8, where the value is 1.

In the method of achieving hard real time by the non-real-time system in the hardware-in-loop simulation in the present disclosure, when the hardware-in-loop simulation task is executed, a virtual hard real time environment can be directly run in a personal computer to achieve hard real time, namely, it can be done without purchasing the real-time system. Further, because all operations are performed locally, the development test efficiency is greatly increased and the flexibility of simulation signal observation and modification is improved.

As shown in FIG. 2, one or more embodiments provide a system for achieving hard real time by a non-real-time system in a hardware-in-loop simulation, which includes a computer device, configured to execute a task creating module and a task thread setting module, where,
the task creating module is configured to create a real-time model task and form a task program;
the task thread setting module is configured to: enable the task program to automatically read computer configuration and determine a number Z of processor kernels of a current computer device; when the number Z of the kernels is not greater than X, set a thread number to n=1 to execute the real-time model task, and otherwise, set the thread number to n=(Z−X)/Y to execute the real-time model task,
wherein Y represents a thread number of one physical core of the processor.

In some embodiments, the functions executed by the task creating module and the task thread setting module can be implemented in the computer device, which can be referred to the specific descriptions of the above method of achieving hard real time by the non-real-time system in the hardware-in-loop simulation and will not be repeated herein.

In some embodiments, an electronic device includes a processor, a readable storage medium, a communication bus and a communication interface, wherein the processor, the readable storage medium and the communication interface communicate with each other via the communication bus; the readable storage medium is configured to store programs of performing the method of achieving hard real-time by the non-real-time system in the hardware-in-loop simulation; and the programs cause the processor to perform the operations corresponding to the method of achieving hard real-time by the non-real-time system in the hardware-in-loop simulation.

In some embodiments, in an electronic device, setting the thread number to n=1 to execute the real-time model task includes:
defining a real-time time interval m for execution of the real-time model task;
obtaining a current time t by the thread in real time, and determining, in real time, whether the current time t is greater than a next execution time t_next,
when t>t_next, determining t_next=t_next+m and executing the real-time model task at the same time.

In some embodiments, in an electronic device, when the real-time model task is executed for a first time, t_next=m, and t=0.

In some embodiments, in an electronic device, setting the thread number to n=(Z−X)/Y to execute the real-time model task includes:
defining a real-time time interval m for execution of the real-time model task;
obtaining, by each thread, the corresponding current time t in real time at the same time, and determining whether the corresponding current time t is greater than a next execution time t_next;
when at least one thread detects t>t_next, the thread attempts to enter a critical section, and the thread successfully entering the critical section performs the following contents in the critical section:
repetitively obtaining the current time t and determining whether the current time t is greater than the next execution time t_next;
when t>t_next, determining t_next=t_next+m and executing the real-time model task at the same time, and exiting the critical section;
when t≤t_next, directly exiting the critical section.

In some embodiments, in an electronic device, those threads unsuccessfully entering the critical section are blocked from entering the critical section until the thread entering the critical section leaves the critical section, and then start a next attempt.

In some embodiments, in an electronic device, the thread successfully entering the critical section is determined by the critical section independently.

In some embodiments, in an electronic device, t_next is a common global variable of various threads.

In some embodiments, in an electronic device, each set thread occupies one processor physical core, including:
an index of the processor physical core occupied by each thread being equal to a value obtained by performing Modulo Operation on the corresponding thread index and a total number of processor physical cores.

An electronic device in some embodiments will be described below from the angle of hardware processing.

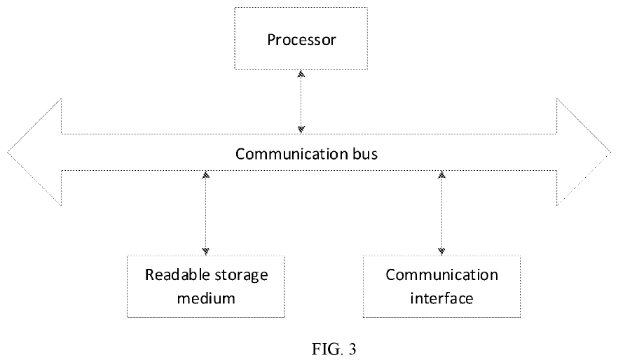

As shown in FIG. 3, the specific implementation of the electronic device is not limited in some embodiments of the present disclosure.

In some embodiments, the communication interface may be RS232, RS485, USB interface or TYPE interface or the like, which may be connected with an external bus adapter. The communication interface may also include wired or wireless network interface. The network interface may optionally include wired interface and/or wireless interface (such as WI-FI interface, Bluetooth interface and the like), which is usually used to establish communication connection between the server and other computer devices.

The readable storage medium or the computer readable storage medium includes at least one type of memories. The memory includes flash memory, harddisk drive, multimedia card, card type memory (e.g. SD memory or the like), magnetic memory, magnetic disk or compact disk or the like. In some embodiments, the memory may be an internal storage unit in the computer device, for example, a harddisk drive of the computer device. In some other embodiments, the memory may also be an external storage device of the computer device, for example, a plug type hard disk drive, a smart media card (SMC), a secure digital (SD) card, a flash card or the like on the computer device. Furthermore, the memory may include both the internal storage unit in the computer device and the external storage device. The memory may be used to not only store an application software installed on the computer device and various types of data, for example, the codes of the computer programs and the like but also temporarily store data already output or to be output.

In some embodiments, the processor may be a central processing unit (CPU), a processor, a controller, a microcontroller, a microprocessor or another data processing chip, which is used to run the program codes in the memory or process the data, for example, execute the computer programs or the like.

In some embodiments, the communication bus may also be an input/output bus, which may be a Peripheral Component Interconnect (PCI) bus, or an Enhanced Industry Standard Architecture (EISA) bus or the like. The bus may include an address bus, a data bus and a control bus and the like.

The processor executes the above programs to perform the steps in the embodiments of the method of achieving hard real time by the non-real-time system in the hardware-in-loop simulation as shown in FIG. 1, for example, the steps S101 to S102 shown in FIG. 1. Alternatively, the processor executes the computer programs to implement the functions of the modules or units in the each device embodiment as above.

In some embodiments, the processor is specifically configured to perform the steps of:
creating a real-time model task and forming a task program;
automatically reading, by the task program, computer configuration and determining a number Z of processor kernels of a current computer device; when the number Z of the kernels is not greater than X, setting a thread number to n=1 to execute the real-time model task, and otherwise, setting the thread number to n=(Z−X)/Y to execute the real-time model task,
wherein Y represents a thread number of one physical core of the processor.

Optionally, as one possible implementation, the processor is further configured to perform the steps of:
setting the thread number to n=1 to execute the real-time model task, including:
defining a real-time time interval m for execution of the real-time model task;
obtaining a current time t by the thread in real time, and determining, in real time, whether the current time t is greater than a next execution time t_next,
when t>t_next, determining t_next=t_next+m and executing the real-time model task at the same time.

Optionally, as one possible implementation, the processor is further configured to perform the following step that:
when the real-time model task is executed for the first time, t_next=m, and t=0.

Optionally, as one possible implementation, the processor is further configured to perform the steps of:
setting the thread number to n=(Z−X)/Y to execute the real-time model task, including:
defining a real-time time interval m for execution of the real-time model task;
obtaining, by each thread, the corresponding current time t in real time at the same time, and determining whether the corresponding current time t is greater than a next execution time t_next;
when at least one thread detects t>t_next, the thread attempts to enter a critical section, and the thread successfully entering the critical section performs the following contents in the critical section:
repetitively obtaining the current time t and determining whether the current time t is greater than a next execution time t_next;
if yes, determining t_next=t_next+m and executing the real-time model task at the same time, and exiting the critical section;
if not, directly exiting the critical section.

Optionally, as one possible implementation, the processor is further configured to perform the following step that:
those threads unsuccessfully entering the critical section are blocked from entering the critical section until the thread entering the critical section leaves the critical section, and then start a next attempt.

Optionally, as one possible implementation, the processor is further configured to perform the following step that:
the thread successfully entering the critical section is determined by the critical section independently.

Optionally, as one possible implementation, the processor is further configured to perform the following step that:
t_next is a common global variable of various threads.

Optionally, as one possible implementation, the processor is further configured to perform the following step that:
each set thread occupies one processor physical core, including:
an index of the processor physical core occupied by each thread being equal to a value obtained by performing Modulo Operation on the corresponding thread index and a total number of processor physical cores.

One or more embodiments further provide a computer readable storage medium configured to store programs of performing the above method of achieving hard real-time by the non-real-time system in the hardware-in-loop simulation in the above embodiments and the programs are executed by a processor to perform the specific steps of the method of achieving hard real-time by the non-real-time system in the hardware-in-loop simulation, which can be referred to the specific descriptions of the above method of achieving hard real-time by the non-real-time system in the hardware-in-loop simulation and will not be repeated herein.

One or more embodiments further provide a computer program product, including computer programs or instructions, where the computer programs or instructions are executed on a computer to cause the computer to perform any one of the above methods of achieving hard real-time by the non-real-time system in the hardware-in-loop simulation.

In some embodiments, a computer readable storage medium, storing computer readable instructions, wherein the computer readable instructions are executed by at least one processor to perform the method:
creating a real-time model task and forming a task program;
automatically reading, by the task program, computer configuration and determining a number Z of processor kernels of a current computer device; when the number Z of the kernels is not greater than X, setting a thread number to n=1 to execute the real-time model task, and otherwise, setting the thread number to n=(Z−X)/Y to execute the real-time model task,
wherein Y represents a thread number of one physical core of the processor.

In some embodiments, a computer program product, including a computer readable storage medium on which computer readable program codes are stored, wherein the computer readable program codes include instructions, which cause at least one processor (one or more computer devices) to perform the following operations:
creating a real-time model task and forming a task program;
automatically reading, by the task program, computer configuration and determining a number Z of processor kernels of a current computer device; when the number Z of the kernels is not greater than X, setting a thread number to n=1 to execute the real-time model task, and otherwise, setting the thread number to n=(Z−X)/Y to execute the real-time model task,
wherein Y represents a thread number of one physical core of the processor.

In the several embodiments provided by the present disclosure, it should be understood that the disclosed device and method can be implemented another way. The above device embodiments are merely illustrative, for example, the flowcharts or block diagrams in the drawings show possible system architectures, functions and operations of the device, method, and computer program product in the several embodiments provided by the present disclosure. Thus, each block in the flowcharts or block diagrams may represent one module, one program fragment or one part of codes. The module, the program fragment or the part of codes includes one or more executable instructions for implementing the specified logic functions. It should be noted that in some alternative embodiments, the functions indicated in the blocks may also be performed in a sequence different from that indicated in the drawings. For example, two continuous blocks can be actually performed basically in parallel, and sometimes may be performed in a reverse sequence, which is dependent on the functions involved. It is further noted that each block in the block diagrams and/or flowcharts and the combinations of the blocks in the block diagrams and/or flowcharts may be implemented by a dedicated hardware-based system for executing specified functions or actions, or by combination of dedicated hardware and computer instructions.

Furthermore, the functional modules in the embodiments of the present disclosure can be integrated into one independent part, or exist as separate modules or two or more of the modules are integrated into one independent part.

The functions, when implemented by software function modules and sold or used as independent products, can be stored in one computer readable storage medium. Based on such understanding, the essence of technical solutions of the present disclosure, or a part contributing to the prior arts or a part of the technical solutions can be embodied in the form of software product. The computer software product is stored in one storage medium which includes several instructions to enable one computer device (for example, a personal computer, a server, or a network device or the like) to perform all or part of the steps of the method of each of the embodiments of the present disclosure.

Enlightened by the ideal embodiments of the present disclosure, relevant workers can, based on the contents of the specification, make various changes and modifications within the scope of protection of the technical idea of the present disclosure. The technical scope of the present disclosure is not limited to the contents of the specification but to the technical scope claimed by the claims.

What is claimed is:

1. A method of achieving hard real-time by a non-real-time system in a hardware-in-loop simulation, comprising:
creating a real-time model task and forming a task program;
automatically reading, by the task program, computer configuration and determining a number Z of kernels of a processor of a current computer device; when the number Z of the kernels is less than or equal to X, setting a thread number to n=1 to execute the real-time model task, and when the number Z of the kernels is greater than X, setting the thread number to n=(Z−X)/Y to execute the real-time model task,
wherein Y represents a thread number of one physical core of the processor.

2. The method of claim 1, wherein,
setting the thread number to n=1 to execute the real-time model task comprises:
defining a real-time time interval m for execution of the real-time model task;
obtaining a current time t by the thread in real time, and determining, in real time, whether the current time t is greater than a next execution time t_next,
when t>t_next, determining t_next=t_next+m and executing the real-time model task at the same time.

3. The method of claim 2, wherein,
when the real-time model task is executed for a first time, t_next=m, and t=0.

4. The method of claim 1, wherein,
setting the thread number to n=(Z−X)/Y to execute the real-time model task comprises:
defining a real-time time interval m for execution of the real-time model task;
obtaining, by each thread, the corresponding current time t in real time at the same time, and determining whether the corresponding current time t is greater than a next execution time t_next;
when at least one thread detects t>t_next, the thread attempts to enter a critical section, and the thread successfully entering the critical section performs the following contents in the critical section:
repetitively obtaining the current time t and determining whether the current time t is greater than the next execution time t_next;
when t>t_next, determining t_next=t_next+m and executing the real-time model task at the same time, and exiting the critical section;
when t≤t_next, directly exiting the critical section.

5. The method of claim 4, wherein,
those threads unsuccessfully entering the critical section are blocked from entering the critical section until the thread entering the critical section leaves the critical section, and then start a next attempt.

6. The method of claim 5, wherein,
the thread successfully entering the critical section is determined by the critical section independently.

7. The method of claim 4, wherein,
t_next is a common global variable of various threads.

8. The method of claim 1, wherein,
each set thread occupies one processor physical core, comprising:
an index of the processor physical core occupied by each thread being equal to a value obtained by performing Modulo Operation on the corresponding thread index and a total number of processor physical cores.

9. A computer readable storage medium, storing computer readable instructions, wherein the computer readable instructions are executed by at least one processor to perform the method according to claim 1.

10. An electronic device, comprising a processor, a readable storage medium, a communication bus and a communication interface, wherein the processor, the readable storage medium and the communication interface communicate with each other via the communication bus;
the readable storage medium is configured to store programs of performing the method of achieving hard real-time by the non-real-time system in the hardware-in-loop simulation according to claim 1; and the programs cause the processor to perform the operations corresponding to the method of achieving hard real-time by the non-real-time system in the hardware-in-loop simulation.

11. The electronic device of claim 10, wherein,
setting the thread number to n=1 to execute the real-time model task comprises:
defining a real-time time interval m for execution of the real-time model task;
obtaining a current time t by the thread in real time, and determining, in real time, whether the current time t is greater than a next execution time t_next,
when t>t_next, determining t_next=t_next+m and executing the real-time model task at the same time.

12. The electronic device of claim 11, wherein,
when the real-time model task is executed for a first time, t_next=m, and t=0.

13. The electronic device of claim 10, wherein,
setting the thread number to n=(Z−X)/Y to execute the real-time model task comprises:
defining a real-time time interval m for execution of the real-time model task;
obtaining, by each thread, the corresponding current time t in real time at the same time, and determining whether the corresponding current time t is greater than a next execution time t_next;
when at least one thread detects t>t_next, the thread attempts to enter a critical section, and the thread successfully entering the critical section performs the following contents in the critical section:
repetitively obtaining the current time t and determining whether the current time t is greater than the next execution time t_next;
when t>t_next, determining t_next=t_next+m and executing the real-time model task at the same time, and exiting the critical section;
when t≤t_next, directly exiting the critical section.

14. The electronic device of claim 13, wherein,
those threads unsuccessfully entering the critical section are blocked from entering the critical section until the thread entering the critical section leaves the critical section, and then start a next attempt.

15. The electronic device of claim 14, wherein,
the thread successfully entering the critical section is determined by the critical section independently.

16. The electronic device of claim 13, wherein,
t_next is a common global variable of various threads.

17. The electronic device of claim 10, wherein,
each set thread occupies one processor physical core, comprising:
an index of the processor physical core occupied by each thread being equal to a value obtained by performing Modulo Operation on the corresponding thread index and a total number of processor physical cores.
